(19) United States
(12) Patent Application Publication
(10) Pub. No.: US 2015/0243769 A1
(43) Pub. Date: Aug. 27, 2015

(54) SEMICONDUCTOR DEVICE AND MANUFACTURING METHOD THEREOF

(71) Applicant: KABUSHIKI KAISHA TOSHIBA, Tokyo (JP)

(72) Inventors: Masakazu GOTO, Yokohama-Shi (JP); Akira HOKAZONO, Kawasaki-Shi (JP)

(21) Appl. No.: 14/309,639

(22) Filed: Jun. 19, 2014

(30) Foreign Application Priority Data
Feb. 24, 2014 (JP) 2014-032858

(51) Int. Cl. H01L 29/66; H01L 29/08; H01L 21/308; H01L 21/225; H01L 21/306; H01L 29/78; H01L 21/324

(52) U.S. Cl. CPC H01L 29/66977; H01L 29/7835; H01L 29/7836; H01L 29/66575; H01L 29/66659; H01L 29/0847; H01L 21/324; H01L 21/2254; H01L 21/30604; H01L 21/3083

(57) ABSTRACT

A semiconductor device includes a semiconductor layer. A gate dielectric film is provided on the semiconductor layer. A gate electrode is provided above the semiconductor layer via the gate dielectric film. A first conductivity-type drain layer is provided in the semiconductor layer on a one-end side of the gate electrode. A second conductivity-type source layer is provided in the semiconductor layer on an other-end side of the gate electrode and below at least a part of the gate electrode. A source extension layer faces at least a part of a bottom surface of the gate electrode via the gate dielectric film and has an impurity concentration lower than that of the source layer. A first conductivity-type pocket layer is provided in the semiconductor layer between the source extension layer and the drain layer. The pocket layer contacts the source extension layer and is separated from the drain layer.

### CROSS REFERENCE TO RELATED APPLICATIONS

This application is based upon and claims the benefit of priority from the prior Japanese Patent Application No. 2014-032858, filed on Feb. 24, 2014, the entire contents of which are incorporated herein by reference.

### FIELD

The embodiments of the present invention relate to a semiconductor device and manufacturing method thereof.

### BACKGROUND

In recent years, a TFET (Tunnel Field-Effect Transistor) using a quantum-mechanical effect of electrons has been developed. The TFET causes BTBT (Band-To-Band Tunneling) between a source and a channel by application of a voltage to a gate electrode. This enables the TFET to realize an on-state.

It is known that the TFET has horizontal elements in which the BTBT occurs in the horizontal direction and vertical elements in which the BTBT occurs in the vertical direction. While the vertical elements generally can increase an on-current by extending an area in which the BTBT occurs because of the structure as compared to the horizontal elements, further increase in the on-current is demanded to improve the TFET performance.

### BRIEF DESCRIPTION OF THE DRAWINGS

FIG. 1 is a cross-sectional view showing an example of a configuration of an N-TFET 100 according to a first embodiment;

FIG. 2A to FIG. 6 are cross-sectional views showing an example of a manufacturing method of the TFET 100 according to the first embodiment;

FIG. 7 is a graph showing characteristics of drain currents Id with respect to gate voltages Vg of TFETs;

FIG. 8 is a cross-sectional view showing an example of a configuration of an N-TFET 200 according to a second embodiment;

FIGS. 9A and 9B are cross-sectional views showing an example of a manufacturing method of the TFET 200 according to the second embodiment;

FIG. 10 is a graph showing characteristics of drain currents Id with respect to gate voltages Vg of TFETs;

FIG. 11 is a cross-sectional view showing an example of a configuration of an N-TFET 300 according to a third embodiment; and

FIG. 12A to FIG. 13B are cross-sectional views showing an example of a manufacturing method of the TFET 300 according to the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to one embodiment includes a semiconductor layer. A gate dielectric film is provided on the semiconductor layer. A gate electrode is provided above the semiconductor layer via the gate dielectric film. A first conductivity-type drain layer is provided in the semiconductor layer on a one-end side of the gate electrode. A second conductivity-type source layer is provided in the semiconductor layer on an other-end side of the gate electrode and below at least a part of the gate electrode. A source extension layer faces at least a part of a bottom surface of the gate electrode via the gate dielectric film and has an impurity concentration lower than that of the source layer. A first conductivity-type pocket layer is provided in the semiconductor layer between the source extension layer and the drain layer. The pocket layer contacts the source extension layer and is separated from the drain layer.

### First Embodiment

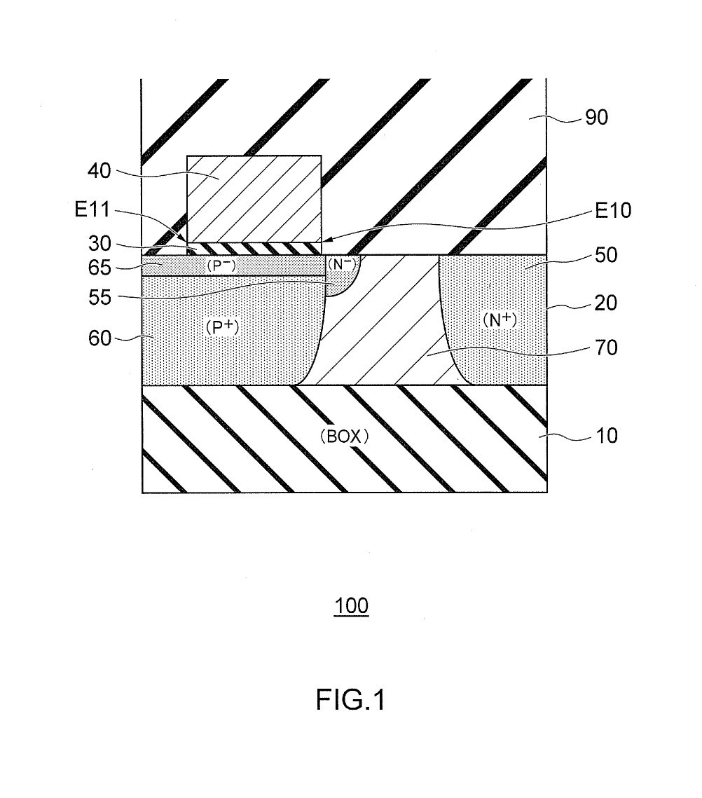

FIG. 1 is a cross-sectional view showing an example of a configuration of an N-TFET 100 according to a first embodiment.

The TFET 100 according to the first embodiment includes a BOX (Buried Oxide) layer 10, a semiconductor layer 20, a gate dielectric film 30, a gate electrode 40, a drain layer 50, a pocket layer 55, a source layer 60, a source extension layer 65, a low concentration layer 70, and an interlayer dielectric film 90.

The semiconductor layer 20 is an SOI (Silicon On Insulator) layer provided on the BOX layer 10.

The gate dielectric film 30 is provided on the semiconductor layer 20. The gate dielectric film 30 is formed of, for example, a silicon dioxide film or a dielectric film having a higher dielectric constant than that of the silicon dioxide film.

The gate electrode 40 is provided above the semiconductor layer 20 via the gate dielectric film 30. The gate electrode 40 is provided above the source layer 60 and the source extension layer 65. That is, the gate electrode 40 has the entire bottom surface facing the source layer 60 or the source extension layer 65 in a gate length direction via the gate dielectric film 30. The gate electrode 40 is formed of, for example, a conducting material such as N-doped polysilicon.

The drain layer 50, which is an N⁺-type layer, is provided in the semiconductor layer 20 at a part on the side of one end E10 of the gate electrode 40. However, the drain layer 50 is not provided just under the gate electrode 40 and is separated from the gate electrode 40. That is, the drain layer 50 is provided at a position offset from the gate electrode 40. Therefore, the bottom surface of the gate electrode 40 does not face the drain layer 50.

The source layer 60, which is a P⁺-type layer, is provided in the semiconductor layer 20 at a part on the side of the other end E11 of the gate electrode 40 or a part below the gate electrode 40. The source layer 60 is formed to face the entire bottom surface of the gate electrode 40 in the gate length direction.

The source extension layer 65, which is a P⁻-type layer, is provided on the source layer 60 and faces the entire bottom surface of the gate electrode 40 via the gate dielectric film 30 in the gate length direction.

That is, the source extension layer 65 is provided between the gate dielectric film 30 and the source layer 60. The source extension layer 65 has an impurity concentration lower than that of the source layer 60 and is formed by implanting P-type impurities (boron, for example) into the semiconductor layer 20. The source extension layer 65 can be, for example, a semiconductor layer having an impurity concentration equal to or lower than 10¹⁶/cm³ (so-called, “intrinsic semiconductor layer”).

The pocket layer 55, which is an N⁻-type layer, is provided in a surface area of the semiconductor layer 20 between the source extension layer 65 and the drain layer 50 or between the source layer 60 and the drain layer 50 and is provided to contact the source extension layer 65 or the source layer 60. The pocket layer 55 contacts the source extension layer 65 or the source layer 60 on the side of the end E10 and is formed in a depth equal to or larger than that of the source extension layer 65. Accordingly, the pocket layer 55 is located all over an interface between the source extension layer 65 and the low concentration layer 70 and thus the source extension layer 65 and the low concentration layer 70 do not contact each other.

Furthermore, the low concentration layer 70 is located between the pocket layer 55 and the drain layer 50 and thus the pocket layer 55 does not contact the drain layer 50. In the first embodiment, the pocket layer 55 does not face the bottom surface of the gate electrode 40 and is not provided just under the gate electrode 40. That is, the pocket layer 55 is offset from the gate electrode 40 on the side of the end E10.

The pocket layer 55 has an impurity concentration higher than that of the low concentration layer 70, which is explained later. It is preferable that the impurity concentration of the pocket layer 55 be lower than that of the drain layer 50. However, the impurity concentration of the pocket layer 55 can be equal to or higher than that of the drain layer 50 depending on an allowable leak current. More specifically, the impurity concentration of the pocket layer 55 suffices to be similar to that of the source extension layer 65. For example, the impurity concentration of the pocket layer 55 suffices to be about 10¹⁷/cm³ to about 10¹⁹/cm³.

The low concentration layer 70 is provided in the semiconductor layer 20 at a part between the drain layer 50 and the pocket layer 55 and between the drain layer 50 and the source layer 60. The low concentration layer 70 separates the drain layer 50 and the pocket layer 55 from each other and the drain layer 50 and the source layer 60 from each other. The low concentration layer 70 is a semiconductor layer lower in the impurity concentration than any of the drain layer 50, the source layer 60, the source extension layer 65, and the pocket layer 55. The low concentration layer 70 can be, for example, a semiconductor layer having an impurity concentration equal to or lower than 10¹⁶/cm³ (so-called, “intrinsic semiconductor layer”).

The interlayer dielectric film 90 covers the gate electrode 40, the drain layer 50, the source layer 60, and the like. The interlayer dielectric film 90 is made of an insulating film such as a TEOS (Tetraethyl Orthosilicate) film or a silicon dioxide film. Although not shown, an interconnection structure including contacts, metal wires, interlayer dielectric films, and the like is also provided in the interlayer dielectric film 90 or on the interlayer dielectric film 90.

In the N-TFET 100 according to the first embodiment, voltages of the same reference sign are applied to the gate electrode 40 and to the drain layer 50, respectively. For example, it is assumed that 0 volt is applied to the source layer 60 and that a positive voltage (1 volt, for example) is applied to the drain layer 50. That is, it is assumed that a reverse bias is applied to a junction between the low concentration layer 70 and the drain layer 50. To bring the TFET 100 to an on-state, a positive voltage is applied to the gate electrode 40.

The TFET 100 is in an off-state when a gate voltage is lower than a threshold voltage of the TFET 100 with reference to a source voltage (0 volt, for example). At that time, tunneling of electrons from the source layer 60 is prohibited. That is, because only quite a small current (an off-leak current) flows between the source layer 60 and the drain layer 50 due to reverse biasing, the TFET 100 can be regarded as being in the off-state.

When a positive voltage is applied to the gate electrode 40 with reference to the source voltage, an area controlled by an electric field from the gate electrode 40 starts to be depleted. When the gate voltage becomes equal to or higher than the threshold voltage with reference to the source voltage, band-to-band transition (hereinafter, also BTBT) of electrons occurs in a part of the semiconductor layer located between the source layer 60 and the drain layer 50. A voltage of the gate electrode 40 at which the BTBT occurs is referred to as a threshold voltage of the TFET 100. The threshold voltage is a gate voltage indicating the on-state of the TFET 100.

The BTBT is caused by modulation of an energy band according to extension of a depletion layer. Because the depletion layer extends longer when the impurity concentration is lower, the BTBT occurs when the energy level of a valance band as an area where the impurity concentration is high becomes almost equal to the energy level of a conduction band as an area where the impurity concentration is low.

According to the first embodiment, the pocket layer 55 is provided in the semiconductor layer 20 at a part between the source extension layer 65 and the drain layer 50 or between the source layer 60 and the drain layer 50. The pocket layer 55 is provided to contact the source extension layer 65 or the source layer 60. That is, the pocket layer 55 is provided to be located between the source extension layer 65 or the source layer 60 and the low concentration layer 70. The pocket layer 55 is higher in the impurity concentration than the low concentration layer 70. Accordingly, the pocket layer 55 can suppress extension of the depletion layer from the source extension layer 65 or the source layer 60 and terminate extension of the depletion layer.

If the pocket layer 55 is not provided, the depletion layer extends greatly from an interface between the source extension layer 65 or the source layer 60 and the low concentration layer 70. For example, because the impurity concentration of the low concentration layer 70 is low, the depletion layer extends greatly toward the low concentration layer 70. Generally, when semiconductors having different impurity concentrations are joined together, a depletion layer extends from a junction therebetween even when an electric field is not applied from outside. The entire bottom surface of the gate electrode 40 faces the source extension layer 65 and thus an electric field of the gate electrode 40 is difficult to apply to the interface between the source extension layer 65 or the source layer 60 and the low concentration layer 70. Accordingly, even when the electric field of the gate electrode 40 is caused to transition to an on-state, the depletion layer extends from the source extension layer 65 or the source layer 60 to the low concentration layer 70. This energy level modulation due to the depletion layer functions as a potential barrier that blocks transmission of charges produced by the BTBT. Therefore, if the pocket layer 55 is not provided, the depletion layer extending from the junction between the source extension layer 65 or the source layer 60 and the low concentration layer 70 interrupts a flow of the charges and thus reduces an on-current of the TFET 100.

On the other hand, according to the first embodiment, the pocket layer 55 is added to the interface between the source extension layer 65 or the source layer 60 and the low concentration layer 70. As mentioned above, the pocket layer 55 suppresses extension of the depletion layer from the source extension layer 65 or the source layer 60 and terminates extension of the depletion layer. Accordingly, charges produced by the BTBT can be transmitted to the drain layer 50 easily and efficiently. That is, because the pocket layer 55 suppresses extension of the depletion layer from the source layer 60 and the source extension layer 65, the influence of the potential barrier mentioned above can be suppressed. As a result, the TFET 100 can keep a high on-current or increase the on-current.

In the first embodiment, the pocket layer 55 is formed deeper than the source extension layer 65 and is provided all over the interface between the source extension layer 65 and the low concentration layer 70. Accordingly, the source extension layer 65 does not contact the low concentration layer 70 and extension of the depletion layer toward the low concentration layer 70 is suppressed.

Furthermore, in the TFET 100 according to the first embodiment, the P⁻-type source extension layer 65 is provided on the P⁺-type source layer 60 and the entire bottom surface of the gate electrode 40 is provided on the source extension layer 65. Therefore, when the TFET 100 is brought to the on-state, the BTBT between the source layer 60 and the source extension layer 65 occurs.

If at least a part of the bottom surface of the gate electrode 40 faces the low concentration layer 70, the electric field from the gate electrode 40 is applied to the low concentration layer 70 as well as to the source extension layer 65 and the source layer 60. Therefore, the BTBT between the source layer 60 or the source extension layer 65 and the low concentration layer 70 as well as the BTBT between the source layer 60 and the source extension layer 65 occurs. In this case, a current observed at the time of switching of a TFET becomes an envelope of tunnel currents corresponding to impurity concentrations and thus steep sub-threshold slope characteristics (hereinafter, also “SS characteristics”) are hard to obtain.

On the other hand, according to the first embodiment, because the gate electrode 40 is not provided on the pocket layer 55 or the low concentration layer 70, the BTBT from the source extension layer 65 to the pocket layer 55 and the low concentration layer 70 and the BTBT from the source layer 60 to the low concentration layer 70 is suppressed. Therefore, the TFET 100 according to the first embodiment is brought to the on-state mainly due to the BTBT between the source layer 60 and the source extension layer 65. Accordingly, the first embodiment can improve the SS characteristics of the TFET 100. Improvement of the SS characteristics reduces an off-current and power consumption.

As described above, according to the first embodiment, reduction in the on-current of the TFET 100 is suppressed by provision of the pocket layer 55. Furthermore, the gate electrode 40 is offset from the drain layer 50, the low concentration layer 70, and the pocket layer 55, thereby improving the SS characteristics of the TFET 100 and reducing the off-current and the power consumption. As a result, the TFET 100 according to the first embodiment can have steep sub-threshold slope characteristics while maintaining the on-current.

In the first embodiment, the entire bottom surface of the gate electrode 40 faces the source extension layer 65 in the gate length direction and does not face the drain layer 50, the low concentration layer 70, or the pocket layer 55. However, the effect of improvement in the on-current is not lost even when a part of the bottom surface of the gate electrode 40 faces the pocket layer 55. That is, the bottom surface of the gate electrode 40 can face the source extension layer 65 and the pocket layer 55 via the gate dielectric film 30 as long as the bottom surface of the gate electrode 40 does not face the drain layer 50 or the low concentration layer 70.

In the first embodiment, the low concentration layer 70 is located between the pocket layer 55 and the drain layer 50, and thus the pocket layer 55 does not contact the drain layer 50 and is separated from the drain layer 50. If the pocket layer 55 contacts the drain layer 50, the pocket layer 55 functions as a part of the drain layer 50. In this case, a junction leak current between the pocket layer 55 (the drain layer 50) and the source extension layer 65 or the source layer 60 is increased by a drain voltage. Therefore, in the first embodiment, the pocket layer 55 is separated from the drain layer 50.

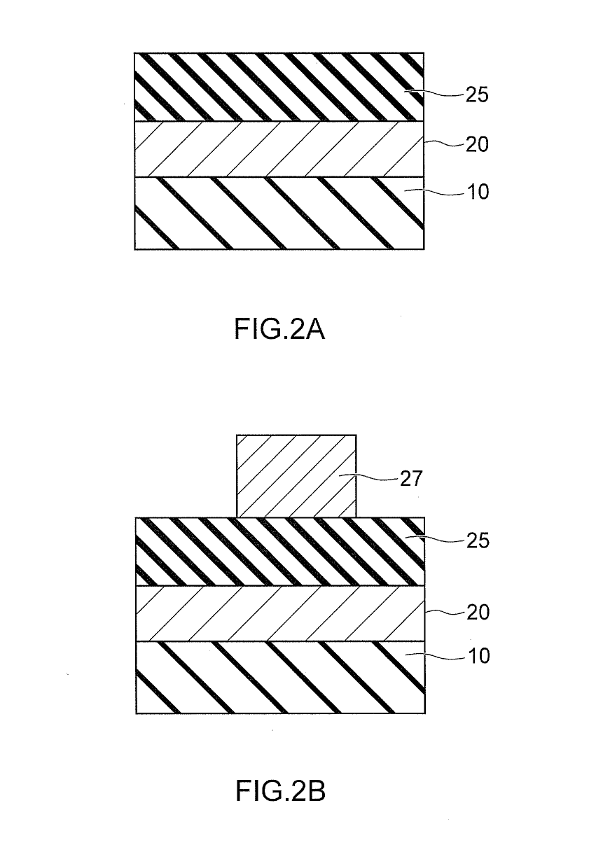

FIG. 2A to FIG. 6 are cross-sectional views showing an example of a manufacturing method of the TFET 100 according to the first embodiment.

As shown in FIG. 2A, a material of a hard mask 25 is first formed on the semiconductor layer 20. The material of the hard mask 25 is an insulating film such as a silicon dioxide film. The semiconductor layer 20 can be an SOI layer of an SOI substrate, a silicon layer formed of a bulk silicon substrate, or a semiconductor layer using a group III-V compound semiconductor substrate. The semiconductor layer 20 can be a semiconductor layer epitaxially grown on an arbitrary substrate. The semiconductor layer 20 can be a SiGe layer epitaxially grown on an SOI substrate or on a bulk substrate. When an SOI substrate is used, the layer 10 is a BOX layer.

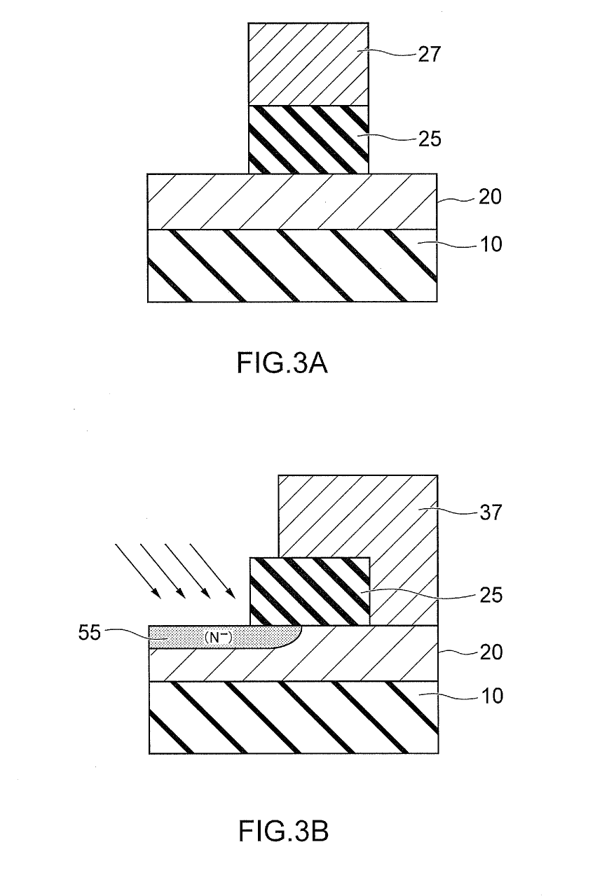

An area other than a formation area of the source layer 60 and a formation area of the drain layer 50 (an intended area between source and drain layers) is then covered by a photoresist 27 using a lithographic technique as shown in FIG. 2B. The hard mask 25 is then etched by a RIE (Reactive Ion Etching) method using the photoresist 27 as a mask as shown in FIG. 3A.

After the photoresist 27 is removed, the formation area of the drain layer 50 is covered with a photoresist 37 using a lithographic technique as shown in FIG. 3B. Ions of N-type impurities (As or P, for example) are then implanted in a tilted direction into a formation area of the pocket layer 55 using the hard mask 25 and the photoresist 37 as a mask. The direction of ion implantation is a direction inclined from a direction perpendicular to the front surface of the semiconductor layer 20 and is a direction toward the formation area of the drain layer 50. That is, the impurities are implanted toward the semiconductor layer 20 located under the hard mask 25.

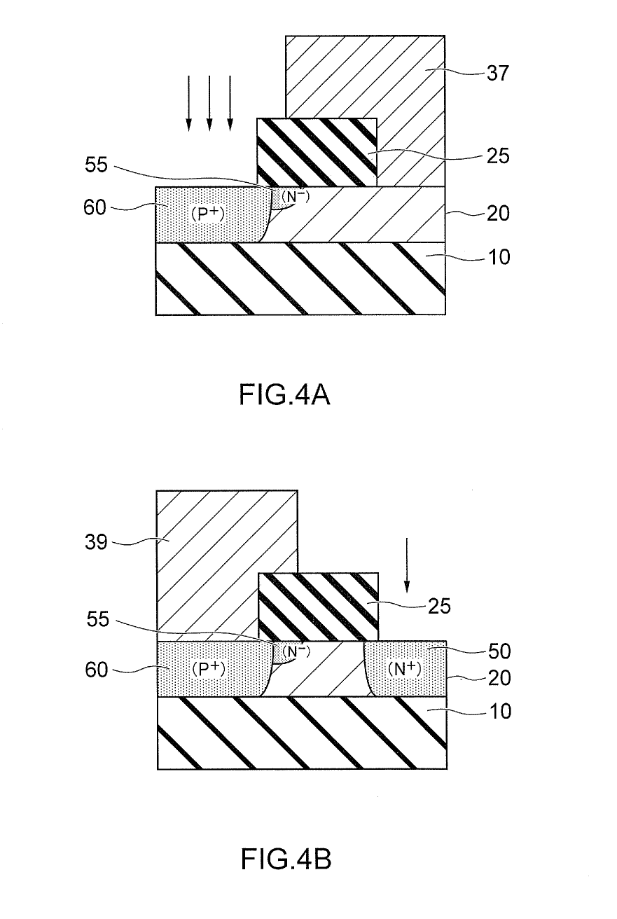

Ions of P-type impurities (B or BF₂, for example) are then implanted into the formation area of the source layer 60 using the hard mask 25 and the photoresist 37 as a mask as shown in FIG. 4A. At that time, the direction of ion implantation is substantially perpendicular to the front surface of the semiconductor layer 20. The source layer 60 has a P-type impurity concentration higher than an N-type impurity concentration of the pocket layer 55. Therefore, the P-type source layer 60 can be formed in the formation area of the source layer 60 while the N-type pocket layer 55 is left behind under the hand mask 25.

After the photoresist 37 is removed, the formation area of the source layer 60 is covered with a photoresist 39 using a lithographic technique as shown in FIG. 4B. Ions of N-type impurities (As or P, for example) are then implanted into the formation area of the drain layer 50 using the hard mask 25 and the photoresist 39 as a mask.

After the photoresist 39 is removed, activation annealing by an RTA (Rapid Thermal Anneal) method or the like is then performed. This activates the drain layer 50, the pocket layer 55, and the source layer 60. In this way, the drain layer 50 and the source layer 60 are formed on opposite sides of the hard mask 25 (an area between source and drain layers), respectively, and the pocket layer 55 is formed in an area adjacent to the source layer 60 and separated from the drain layer 50 under the hard mask 25. When the drain layer 50, the source layer 60, and the pocket layer 55 are formed, the processes of ion implantation shown in FIG. 3B to FIG. 4B can be performed in an order different from that mentioned above.

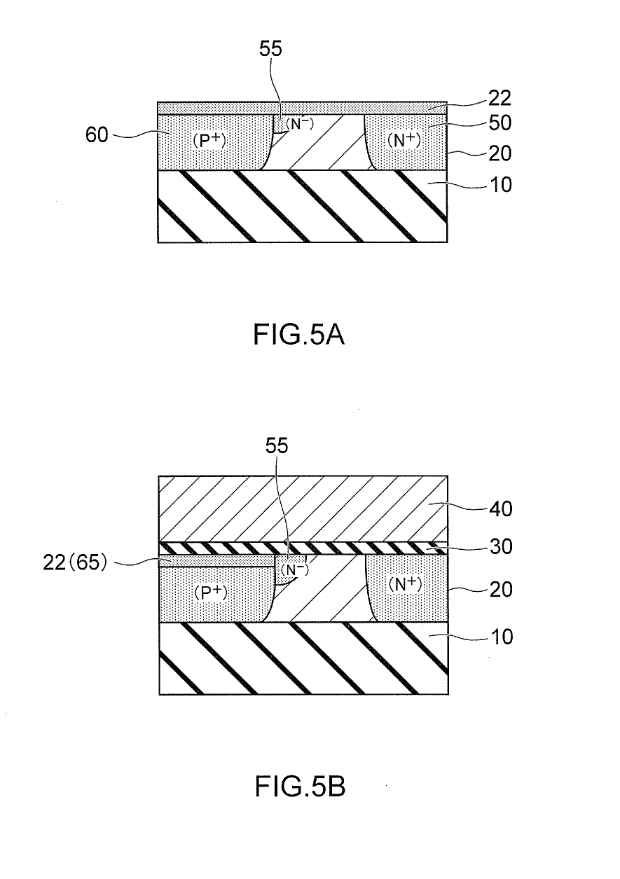

After the hard mask 25 is removed by wet etching, an intrinsic semiconductor layer 22 is then epitaxially grown on the semiconductor layer 20 by an epitaxial CVD (Chemical Vapor Deposition) method as shown in FIG. 5A. The following explanations are performed regarding the intrinsic semiconductor layer 22 as a part of the semiconductor layer 20. The epitaxially-grown semiconductor layer 20 can be formed of, for example, Ge or Si containing Ge such as Si₁₋ₓGeₓ, or can be an arbitrary stack layer structure including Si and Si containing Ge.

The semiconductor layer 20 (the intrinsic semiconductor layer 22) is then thermally oxidized to form the gate dielectric film 30 on the semiconductor layer 20 as shown in FIG. 5B. The thermal oxidization process diffuses the impurities in the source layer 60, the pocket layer 55, and the drain layer 50 to the intrinsic semiconductor layer 22 to some extent. Accordingly, the P⁻-type source extension layer 65 is formed on the front surface of the P⁺-type source layer 60. A material of the gate electrode 40 is then deposited on the gate dielectric film 30.

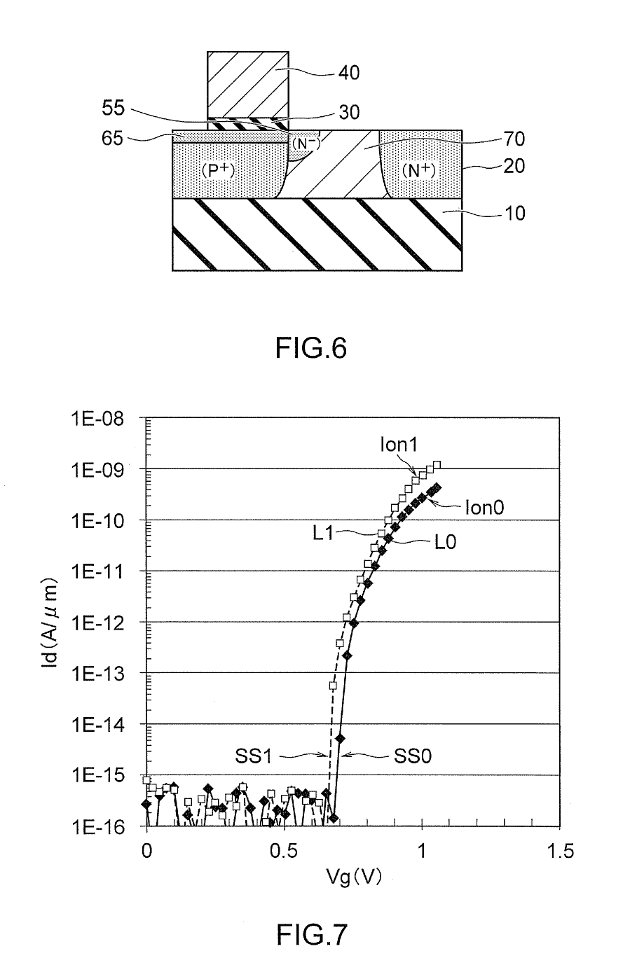

The material of the gate electrode 40 is then processed using a lithographic technique and the RIE method. In this way, a structure shown in FIG. 6 is obtained.

The interlayer dielectric film 90, contacts (not shown), metal wires (not shown), and the like are then formed, so that the TFET 100 shown in FIG. 1 is completed.

According to the first embodiment, the impurities in the pocket layer 55 and the impurities in the source layer 60 are implanted using the photoresist 37 in common. Therefore, the TFET 100 according to the first embodiment can be manufactured by adding only one process of implanting the impurities in the pocket layer 55 to the existing manufacturing process. The layout of the gate electrode 40 can be obtained only by changing a mask pattern. That is, the manufacturing method according to the first embodiment can manufacture the TFET 100 having steep sub-threshold slope characteristics while maintaining the on-current easily and at a low cost.

As described above, according to the first embodiment, the gate electrode 40 is offset toward the source layer 60 and the source extension layer 65. This prevents the electric field of the gate electrode 40 from being applied to the low concentration layer 70 and from modulating the energy band of the low concentration layer 70. Therefore, the BTBT from the source layer 60 or the source extension layer 65 to the low concentration layer 70 is suppressed. As a result, a tunneling path of the BTBT becomes quite a short path of a distance from the source layer 60 to the source extension layer 65 near the gate electrode 40. Accordingly, the TFET 100 can have quite steep SS characteristics. A circuit that uses the TFET 100 becomes a circuit with low power consumption.

Furthermore, the pocket layer 55 suppresses a potential barrier caused by a depletion layer that extends from the source layer 60 and the source extension layer 65 to the low concentration layer 70. This enables the TFET 100 to keep or improve the on-current.

FIG. 7 is a graph showing characteristics of drain currents Id with respect to gate voltages Vg of TFETs. A line L0 indicates a simulation result showing a drain current Id of a TFET (hereinafter, TFET 0) not including the pocket layer 55. A line L1 indicates a simulation result showing a drain current Id of the TFET 100 including the pocket layer 55.

A slope of the drain current Id at the time of rising indicates the SS characteristics. Therefore, a steeper slope of the drain current Id at the time of rising indicates better SS characteristics. In this case, a slope SS1 of the line L1 at the time of rising is substantially equal to or steeper than a slope SS0 of the line L0 at the time of rising. Therefore, the TFET 100 is substantially equal to or better than the TFET 0 in the SS characteristics.

The magnitude of the drain current Id after rising indicates the on-current. Therefore, a larger drain current Id after rising indicates a better on-current. An on-current Ion1 of the TFET 100 is larger than an on-current Ion0 of the TFET 0. Accordingly, the TFET 100 is larger than the TFET 0 in the on-current.

As described above, with reference to the graph shown in

FIG. 7, it can be understood that the TFET 100 including the pocket layer 55 has the SS characteristics equal to or higher than those of the TFET 0 not including the pocket layer 55 and has the on-current larger than that of the TFET 0. That is, the pocket layer 55 can increase the on-current of the TFET 100.

### Second Embodiment

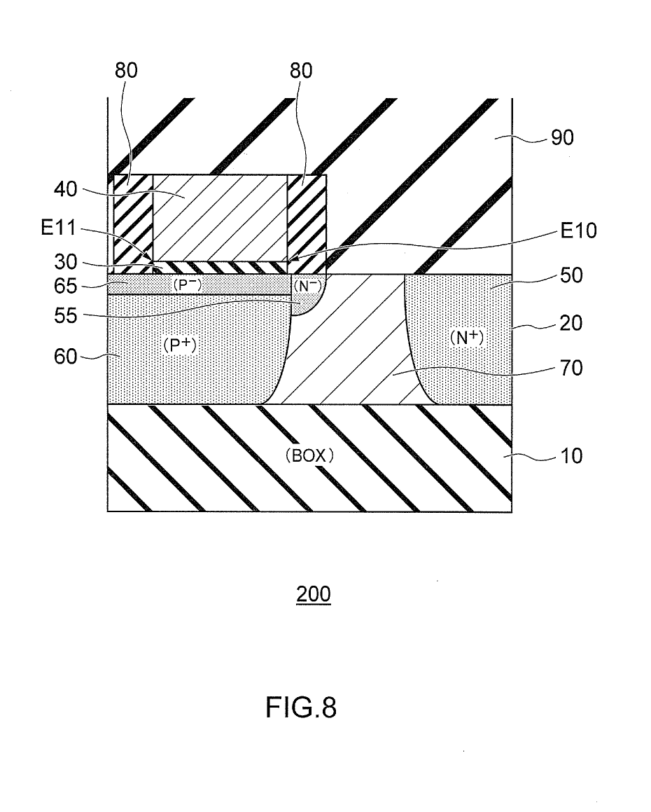

FIG. 8 is a cross-sectional view showing an example of a configuration of an N-TFET 200 according to a second embodiment. The TFET 200 according to the second embodiment is different from that according to the first embodiment in further including a doped spacer 80.

The doped spacer 80 is provided on side surfaces of the gate electrode 40 and is also provided on the pocket layer 55. To form the pocket layer 55, the doped spacer 80 contains the same N-type impurities (phosphorus or arsenic, for example) as those in the pocket layer 55.

Other configurations of the second embodiment can be identical to corresponding ones of the first embodiment. Therefore, the second embodiment can also achieve effects identical to those of the first embodiment.

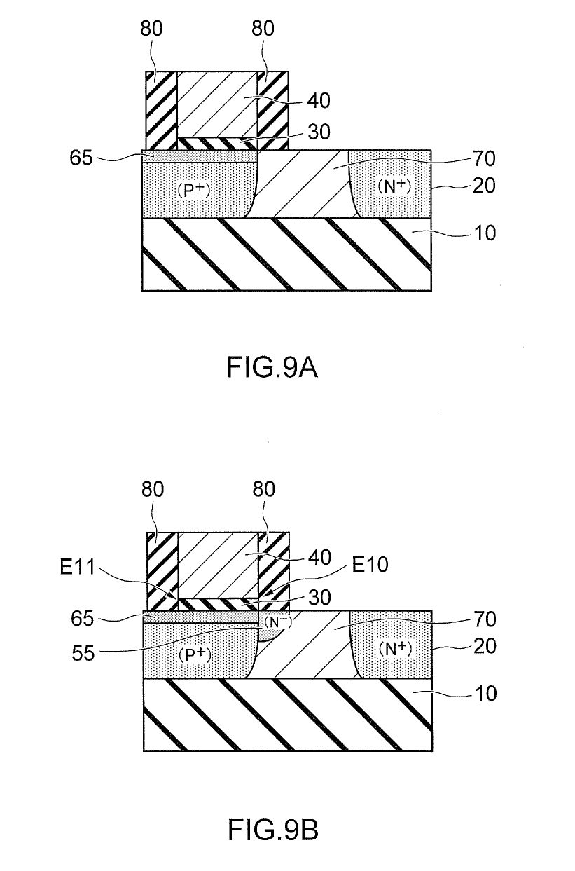

FIGS. 9A and 9B are cross-sectional views showing an example of a manufacturing method of the TFET 200 according to the second embodiment. Processes explained with reference to FIG. 2A to FIG. 6 are first performed. In the second embodiment, ion implantation for forming the pocket layer 55 shown in FIG. 3B is not performed. Therefore, the pocket layer 55 is not formed yet at a stage where the process explained with reference to FIG. 6 has been performed.

A material of the doped spacer 80 is then deposited on the gate electrode 40 and the semiconductor layer 20 by the CVD method. The material of the doped spacer 80 is an insulating film containing N-type impurities and is, for example, PSG (Phosphorus Doped Silicon Glass). The material of the doped spacer 80 is then anisotropically etched by the RIE method. Accordingly, the doped spacer 80 is left behind as a side wall film on the side surfaces of the gate electrode 40 as shown in FIG. 9A.

The N-type impurities are then diffused from the doped spacer 80 to the semiconductor layer 20 by the RTA method or the like as shown in FIG. 9B. In this way, the pocket layer 55 is formed in a front surface area of the semiconductor layer 20 under the doped spacer 80.

The doped spacer 80 is formed also on the side of the end E11 of the gate electrode 40. Therefore, an N-type diffusion layer can be formed also in the semiconductor layer 20 on the side of the end E11 of the gate electrode 40. The characteristics of the TFET 200 are not affected even when the N-type diffusion layer is located in the semiconductor layer 20 on the side of the end E11 of the gate electrode 40. Of course, there is no need to form the N-type diffusion layer on the side of the end E11 of the gate electrode 40. In such a case, the P⁻-type source extension layer 65 is maintained on the side of the end E11 of the gate electrode 40.

The interlayer dielectric film 90, contacts (not shown), metal wires (not shown), and the like are then formed, so that the TFET 200 shown in FIG. 8 is completed.

According to the second embodiment, the doped spacer 80 is formed as the side wall film of the gate electrode 40 and the doped spacer 80 diffuses the impurities to the semiconductor layer 20 located thereunder. Therefore, the doped spacer 80 has a function as the side wall film of the gate electrode 40 and a function to form the pocket layer 55 in a self-aligned manner. Because the pocket layer 55 is formed in a self-aligned manner, the pocket layer 55 can be formed accurately at a position in the semiconductor layer 20 along the side surfaces of the gate electrode 40 in the second embodiment.

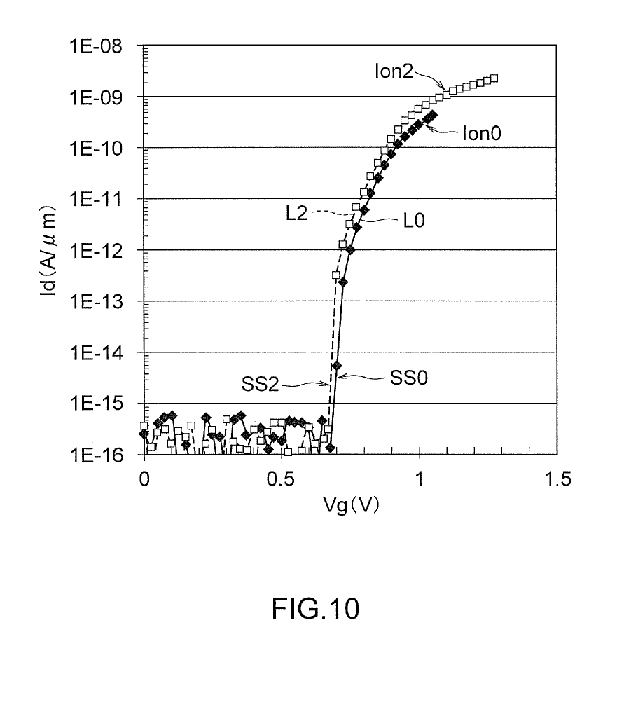

FIG. 10 is a graph showing characteristics of drain currents Id with respect to gate voltages Vg of TFETs. A line L0 shows a simulation result indicating a drain current Id of a TFET 0 not including the doped spacer 80 and the pocket layer 55. A line L2 shows a simulation result indicating a drain current Id of the TFET 200 including the doped spacer 80 and the pocket layer 55.

A slope SS2 of the line L2 at the time of rising is substantially equal to or steeper than a slope SS0 of the line L0 at the time of rising. Therefore, the TFET 200 is substantially equal to or better than the TFET 0 in the SS characteristics.

Meanwhile, an on-current Ion2 of the TFET 200 is larger than an on-current Ion0 of the TFET 0. Therefore, the TFET 200 is larger than the TFET 0 in the on-current.

As described above, with reference to the graph shown in FIG. 10, it can be understood that the TFET 200 including the doped spacer 80 and the pocket layer 55 has the SS characteristics equal to or higher than the TFET 0 not including the pocket layer 55 and has the on-current larger than the TFET 0. That is, also when there is the doped spacer 80, the TFET 200 can achieve the same effect as in the TFET 100.

### Third Embodiment

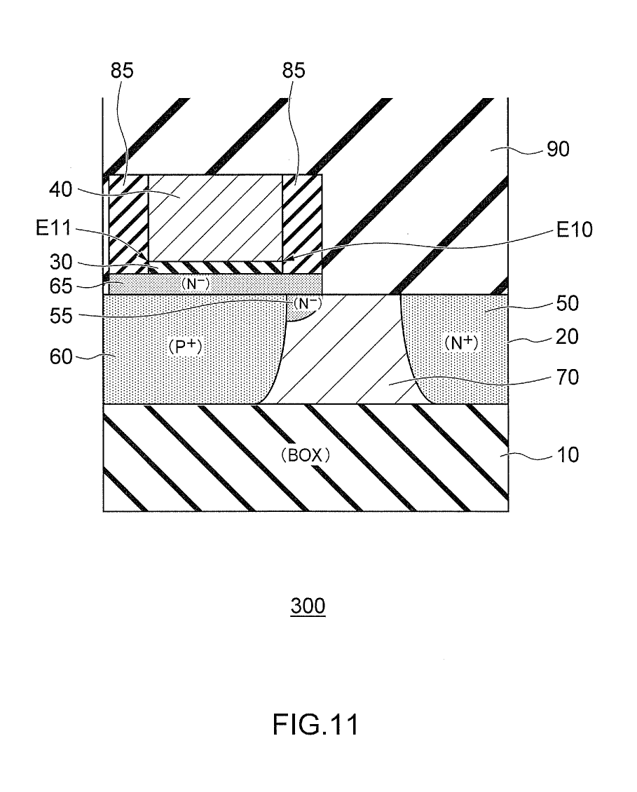

FIG. 11 is a cross-sectional view showing an example of a configuration of an N-TFET 300 according to a third embodiment. The TFET 300 according to the third embodiment is different from that according to the second embodiment in that the source extension layer 65 is an N⁻-type diffusion layer as the pocket layer 55.

The source extension layer 65 is of the opposite conductivity type to that of the source layer 60 and is of the same conductivity type as that of the drain layer 50 and the pocket layer 55. An energy band is curved in a direction in which the BTBT is likely to occur because the source extension layer 65 and the source layer 60 have the opposite conductivity types. This lowers a threshold voltage of the TFET 300. Accordingly, the TFET 300 can operate at a low gate voltage. An N-type impurity concentration of the source extension layer 65 can be equal to or lower than that of the pocket layer 55. Alternatively, the N-type impurity concentration of the source extension layer 65 can be similar to that of the low concentration layer 70.

As shown in FIG. 11, a part of the semiconductor layer 20 is recessed. This is to prevent the drain layer 50 and the pocket layer 55 from conducting to each other for a manufacturing reason as explained later.

Other configurations of the third embodiment can be identical to corresponding ones of the first embodiment. Therefore, the third embodiment can also achieve effects identical to those of the first embodiment. In addition, the third embodiment can be combined with the second embodiment. With this combination, the third embodiment can also achieve effects identical to those of the second embodiment.

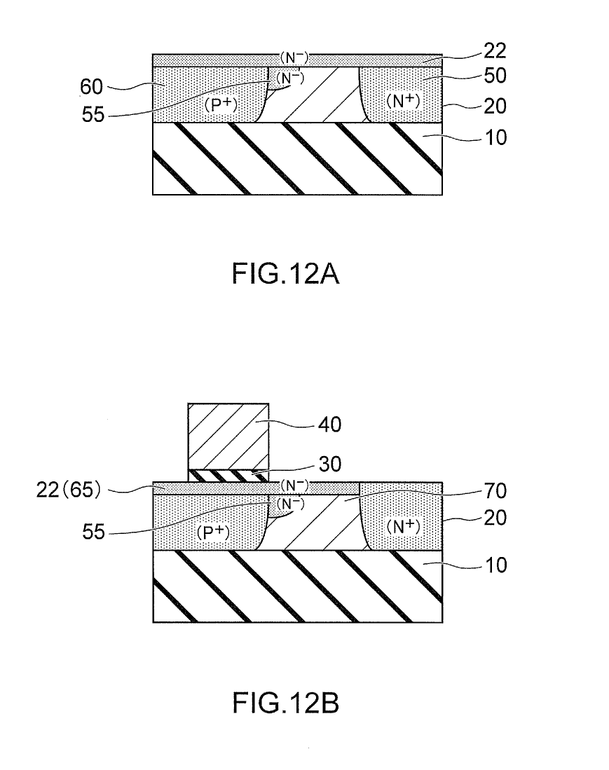

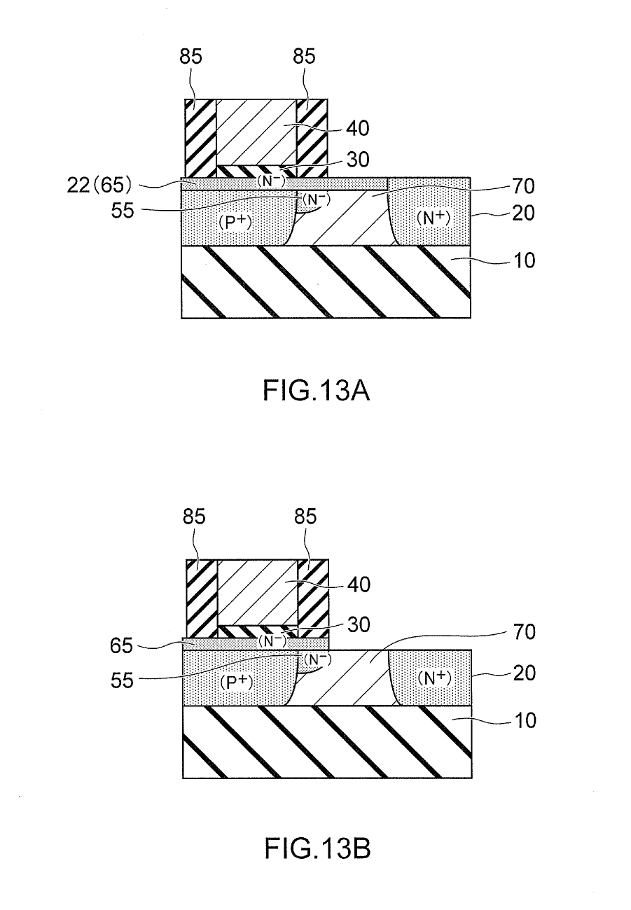

FIG. 12A to FIG. 13B are cross-sectional views showing an example of a manufacturing method of the TFET 300 according to the third embodiment. The processes explained with reference to FIG. 2A to FIG. 5A are first performed to obtain a structure shown in FIG. 5A. However, the semiconductor layer 22 is an epitaxial layer containing N-type impurities (phosphorus, for example) as shown in FIG. 12A. For example, an epitaxial layer is grown on the semiconductor layer 20 while the N-type impurities are contained in Si by the CVD method. This forms an N⁻-type silicon layer as the semiconductor layer 22.

As explained with reference to FIG. 5B and FIG. 6, the gate dielectric film 30 and the gate electrode 40 are then formed on the source extension layer 65. In this way, a structure shown in FIG. 12B is obtained.

A spacer 85 is then formed on opposite side surfaces of the gate electrode 40 by the CVD method and the RIE method as shown in FIG. 13A. A material of the spacer 85 is an insulating film such as a silicon dioxide film. The spacer 85 may contain impurities or no impurities.

An upper part of the semiconductor layer 20 is then etched by the RIE method using the gate electrode 40 and the spacer 85 as a mask. This removes the N⁻-type silicon layer 22 on the drain layer 50 and on the low concentration layer 70 as shown in FIG. 13B. By recessing a part of the semiconductor layer 20 in this way, the drain layer 50 is electrically disconnected from the pocket layer 55 and the source extension layer 65.

The interlayer dielectric film 90, contacts (not shown), metal wires (not shown), and the like are then formed, so that the TFET 300 shown in FIG. 11 is completed.

According to the third embodiment, the drain layer 50 and the pocket layer 55 are electrically disconnected from each other. Therefore, an off-leak current of the TFET 300 can be suppressed.

The third embodiment can be combined with the second embodiment. In this case, it suffices to form the doped spacer 80 instead of the spacer 85 as the side wall film formed on the opposite side surfaces of the gate electrode 40. Further, it suffices to form the pocket layer 55 not by the ion implantation but by solid-phase diffusion from the doped spacer 80 through thermal treatment.

Furthermore, in the third embodiment, it is unnecessary to purposely form the pocket layer 55 by the ion implantation or the solid-phase diffusion. When the pocket layer 55 is not provided, the N⁻-type silicon layer 22 is left behind just under the spacer 85 in FIG. 13B. The N⁻-type silicon layer 22 under the spacer 85 can function as the pocket layer 55. Therefore, there is no need to perform the implantation process or the diffusion process for the pocket layer 55. This facilitates the manufacturing process of the TFET 300.

In the above embodiments, an N-TFET has been explained. However, needless to mention, the above embodiments can be also applied to a P-TFET. In the case of a P-TFET, the source layer 60 is an N-type diffusion layer and the drain layer 50 is a P-type diffusion layer.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a gate dielectric film on the semiconductor layer;
a gate electrode above the semiconductor layer via the gate dielectric film;
a first conductivity-type drain layer in the semiconductor layer on a one-end side of the gate electrode;
a second conductivity-type source layer in the semiconductor layer on an other-end side of the gate electrode and below at least a part of the gate electrode;
a source extension layer facing at least a part of a bottom surface of the gate electrode via the gate dielectric film and having an impurity concentration lower than that of the source layer; and
a first conductivity-type pocket layer in the semiconductor layer between the source extension layer and the drain layer, the pocket layer contacting the source extension layer and being separated from the drain layer.

2. The device of claim 1, further comprising a low concentration layer in the semiconductor layer between the pocket layer and the drain layer, the low concentration layer having an impurity concentration lower than those of the drain layer, the source layer, the source extension layer, and the pocket layer.

3. The device of claim 1, wherein the bottom surface of the gate electrode faces the source extension layer and the pocket layer via the gate dielectric film.

4. The device of claim 1, wherein the pocket layer has a depth equal to or larger than that of the source extension layer.

5. The device of claim 1, wherein the pocket layer does not face the bottom surface of the gate electrode.

6. The device of claim 1, wherein the drain layer is located in the semiconductor layer at a position offset from the gate electrode.

7. The device of claim 1, wherein the pocket layer has an impurity concentration substantially equal to that of the source extension layer.

8. The device of claim 1, wherein the pocket layer has an impurity concentration from 10¹⁷/cm³ to 10¹⁹/cm³.

9. The device of claim 1, wherein the source extension layer contains first conductivity-type impurities.

10. The device of claim 1, wherein the source extension layer contains second conductivity-type impurities.

11. The device of claim 1, further comprising:
a spacer containing first conductivity-type impurities on side surfaces of the gate electrode, wherein
the pocket layer is formed in the semiconductor layer below the spacer to be self-aligned with the spacer.

12. A manufacturing method of a semiconductor device, the method comprising:
introducing first conductivity-type impurities for forming a drain layer into a drain-layer formation area using a first mask material as a mask, the first mask material covering a source-layer formation area and an intended area between source and drain layers in a semiconductor layer, while introducing second conductivity-type impurities for forming a source layer into the source-layer formation area using a second mask material as a mask, the second mask material covering the drain-layer formation area and the intended area between source and drain layers in the semiconductor layer;
introducing first conductivity-type impurities for forming a pocket layer into an area of the semiconductor layer, the area being adjacent to the source-layer formation area and being separated from the drain-layer formation area; and
forming a gate electrode above the semiconductor layer via a gate dielectric film, an entire bottom surface of the gate electrode facing the source layer, or the source layer and the pocket layer, in a gate length direction.

13. The method of claim 12, wherein
the second conductivity-type impurities for forming the source layer are introduced substantially perpendicularly to the source-layer formation area using the second mask material as a mask, and
the first conductivity-type impurities for forming the pocket layer are introduced atilt to the area of the semiconductor layer using the second mask material as a mask.

14. The method of claim 13, wherein
the second conductivity-type impurities are introduced substantially perpendicularly to the source-layer formation area with an impurity concentration higher than that of the first conductivity-type impurities introduced atilt to the area of the semiconductor layer.

15. The method of claim 12, wherein the first conductivity-type impurities for forming the pocket layer are introduced from a spacer by thermally treating the spacer after formation of the gate electrode, the spacer being formed on side surfaces of the gate electrode and containing first conductivity-type impurities.

16. The method of claim 12, further comprising:
after introducing the second conductivity-type impurities for forming the source layer,
growing an epitaxial layer on the semiconductor layer; and
thermally treating the epitaxial layer and the semiconductor layer and diffusing the second conductivity-type impurities to the epitaxial layer on the source-layer formation area to form a source extension layer.

17. A manufacturing method of a semiconductor device, the method comprising:
introducing first conductivity-type impurities for forming a drain layer into a drain-layer formation area using a first mask material as a mask, the first mask material covering a source-layer formation area and an intended area between source and drain layers in a semiconductor layer, while introducing second conductivity-type impurities for forming a source layer into the source-layer formation area using a second mask material as a mask, the second mask material covering the drain-layer formation area and the intended area between source and drain layers in the semiconductor layer;
thermally treating the semiconductor layer to form the first conductivity-type drain layer and the second conductivity-type source layer;
growing a first conductivity-type semiconductor layer on the semiconductor layer to form a first conductivity-type source extension layer;
forming a gate electrode above the source layer via the source extension layer and a gate dielectric film, the gate electrode being offset from the drain layer;
forming a spacer on side surfaces of the gate electrode; and
etching the grown semiconductor layer using the gate electrode and the spacer as a mask to electrically disconnect the source extension layer from the drain layer.

18. The method of claim 17, further comprising introducing first conductivity-type impurities for forming a pocket layer into an area of the semiconductor layer, the area being adjacent to the source-layer formation area and being separated from the drain-layer formation area.

19. The method of claim 18, wherein
the second conductivity-type impurities for forming the source layer are introduced substantially perpendicularly to the source-layer formation area using the second mask material as a mask, and
the first conductivity-type impurities for forming the pocket layer are introduced atilt to the area of the semiconductor layer using the second mask material as a mask.

20. The method of claim 18, wherein
the spacer contains first conductivity-type impurities, and
the first conductivity-type impurities for forming the pocket layer are introduced from the spacer by thermally treating the spacer.
